(19) United States
(12) Patent Application Publication
(10) Pub. No.: US 2002/0177253 A1
(43) Pub. Date: Nov. 28, 2002

(54) Process for making a high voltage NPN Bipolar device with improved AC performance

(75) Inventors: Jeffrey B. Johnson, Essex Junction, VT (US); Alvin J. Joseph, Williston, VT (US); Vidhya Ramachandran, Essex Junction, VT (US)

Correspondence Address: Steven Fischman, Esq., Scully, Scott, Murphy & Presser, 400 Garden City Plaza, Garded City, NY, 11530, US

(73) Assignee: INTERNATIONAL BUSINESS MACHINES CORPORATION, ARMONK, NY (US)

(21) Appl. No.: 09/866,319

(22) Filed: May 25, 2001

(51) Int. Cl. H01L 21/00

(52) U.S. Cl. 438/91

(57) ABSTRACT

A method of improving the speed of a heterojunction bipolar device without negatively impacting ruggedness of the device is provided. This method includes the steps of providing a structure that includes at least a bipolar device region, the bipolar device region comprising at least a collector region formed over a sub-collector region; and forming an n-type dopant region within the collector region, wherein the n-type dopant region has a vertical width that is less than about 2000 Å and a peak concentration that is greater than a peak concentration of the collector region. The present invention also provides a method of fabricating a heterojunction bipolar transistor device as well as the device itself which can be used in various applications including as a component for a mobile phone, a component of a personal digital assistant and other like applications wherein speed and ruggedness are required.

### DESCRIPTION

1. Field of the Invention

The present invention relates to semiconductor bipolar devices, and more particularly to a high-voltage silicon germanium (SiGe) bipolar transistor having improved AC performance.

2. Background of the Invention

Significant growth in both high-frequency wired and wireless markets has introduced new opportunities where compound semiconductors have unique advantages over bulk complementary metal oxide semiconductor (CMOS) technology. With the rapid advancement of epitaxial-layer pseudomorphic SiGe deposition processes, epitaxial-base SiGe heterojunction bipolar transistors have been integrated with main stream advanced CMOS development for wide market acceptance, providing the advantages of SiGe technology for analog and radio frequency (RF) circuitry while maintaining the full utilization of the advanced CMOS technology base for digital logic circuitry.

SiGe heterojunction bipolar transistor devices are replacing Si and GaAs bipolar junction devices as the primary element in many RF/analog applications mainly due to the ability to provide integrated solutions that reduce cost and chip size without compromising performance. This is especially the case for applications such as cellular or mobile phones. One of the key challenges in Si-based technologies for mobile phone applications is providing an RF power transistor that possesses both high-speeds and ruggedness (i.e., a high capability of withstanding very high-voltage spikes). Transistor speed is typically correlated to cutoff frequency, which is determined by the emitter-collector delay time (i.e., how long it takes an electron, in an NPN transistor, or hole, in a PNP transistor, to travel from the emitter to collector), whereas ruggedness is typically correlated to breakdown voltage BV, particularly the collector-emitter breakdown voltage (with open base) BV_{ceo}.

In bipolar transistors, the cutoff frequency and breakdown voltage are not complementary; therefore to get more speed, one typically has to compromise the ruggedness of the device, and vice versa. For example, in order for SiGe heterojunction bipolar transistor devices to withstand high-operating voltages, the collector region must be lightly doped. However, lightly doped collector regions degrade the AC performance of the device since, for a given current density, the Kirk effect (i.e., cutoff frequency decreases due to high current effects) appears sooner. This means that the AC figures of merit of the device (ft and fmax) are also degraded.

Palestri, et al. “A Better Insight into the Performance of Silicon BJT's Featuring Highly Nonuniform Collector Doping Profile” IEEE Transactions of Electron Devices, Vol. 47, No. 5, pp. 1044 (May 2000) investigate the effects, via Monte Carlo and drift-diffusion simulations, of highly nonuniform collector doping profiles on the speed and breakdown voltage of Si bipolar transistors. Although spike-like profiles are shown in the Palestri, et al. article, no process is mentioned or proposed on how to obtain the same.

Van Noort, et al. “Reduction of UHF Power Transistor Distortions with a Non-Uniform Collector Doping Profile” IEEE BCTM 7.2, pp. 126 (2000) propose the use of a spike profile for reduction of distortions in very high-voltages (on the order of about 50V or higher) power transistors. Specifically, arsenic (i.e., As), grown epitaxially, is employed in the Van Noort, et al. article for the reduction of distortions in such transistors. It is noted that epitaxial growth of As is however not compatible with present BiCMOS (bipolar complementary metal oxide semiconductor) processes.

In view of the above problems with prior art SiGe heterojunction bipolar transistor devices, there is a continued interest for providing new and improved SiGe heterojunction bipolar transistor devices that are integrated into a BiCMOS process flow in which the AC performance of the device is improved without degrading the transistor speed and ruggedness requirements of such devices.

### SUMMARY OF THE INVENTION

One object of the present invention is to provide a method for improving the AC performance of a SiGe heterojunction bipolar transistor device such that the same can be used in a wide variety of applications such as a component in mobile phones.

Another object of the present invention is to provide a method for fabricating a heterojunction bipolar transistor device in which high-transistor speeds and ruggedness requirements of such a device is maintained.

A still further object of the present invention is to provide a method of fabricating a heterojunction bipolar transistor device in which the processing steps are compatible and are easy to implement with existing BiCMOS technologies.

A yet further object of the present invention is to provide a method of fabricating a heterojunction bipolar transistor device that can withstand high-operating voltages.

These and other objects and advantages are achieved in the present invention by a method of fabricating a semiconductor device comprising the step of providing a collector having a first doping type, said collector comprising a sub-collector and a diffusion. The diffusion is over said sub-collector, and the diffusion has the same doping type as the collector. The next step is to form a base and then to form an emitter. The diffusion has a vertical width sufficiently narrow to avoid lowering collector-base breakdown voltage and a doping sufficiently high to restrict base widening when the base-emitter junction is forward biased.

The process involves performing a low-energy, medium-dose n-type dopant implantation after formation of the sub-collector region so as to create a very narrow, medium-dose spike in the low-doped collector region of high-voltage heterojunction bipolar transistors. This n-type dopant spike created by the present invention is heavy enough to significantly delay the onset of the Kirk effect, yet it is narrow enough to avoid creating a high-electrical field region of sufficient duration to degrade the breakdown characteristics of the device. The present invention thus leverages the non-stationary nature of carrier dynamics in semiconductors: viz., that both holes and electrons in semiconductors do not respond instantaneously to abrupt changes in electric field but rather take a characteristic time (called a ‘relaxation time’) to respond, to move the heterojunction bipolar transistor off the so-called Johnson limit (the relationship between cutoff frequency and breakdown voltage) characteristic of that type of transistor showing the tradeoff between breakdown voltage and cutoff frequency.

More specifically, the present invention provides a SiGe bipolar transistor having an n-type dopant region at the junction between the base and the collector region, wherein the n-type dopant region is narrow and has a peak concentration that is greater than the peak concentration of the collector.

One aspect of the present invention thus relates to a method of providing a narrow n-type dopant region in a heterojunction bipolar transistor structure which is capable of improving the AC performance of the resultant structure.

The invention includes the step of forming an n-type dopant region above the sub-collector, wherein said n-type dopant region has a vertical width that is less than about 2000 Å and a peak concentration that is greater than a peak concentration of said collector region.

Another aspect of the present invention comprises the fabrication of a heterojunction bipolar transistor structure that includes the steps of:

(a) providing a structure that includes at least a bipolar device region, said bipolar device region comprising at least a collector region formed over a sub-collector region;

(b) forming an n-type dopant region within said collector region, wherein said n-type dopant region has a vertical width that is less than about 2000 Å and a peak concentration that is greater than a peak concentration of said collector region;

(c) depositing a SiGe-containing layer on said bipolar device region, said SiGe-containing layer comprising polycrystalline regions abutting a single-crystal region;

(d) forming a patterned insulator on said SiGe-containing layer, wherein said patterned insulator includes an opening that exposes a portion of said single-crystal region; and

(e) forming an emitter polysilicon on said patterned insulator and in said opening.

Another aspect of the present invention relates to a heterojunction bipolar transistor having improved AC performance. Specifically, the inventive heterojunction bipolar transistor comprises:

an emitter, a base, a collector, a base-emitter junction, and a base-collector junction, wherein said collector comprises a sub-collector and a diffusion between said subcollector and said base-collector junction, wherein said diffusion has a vertical width sufficiently narrow to avoid lowering collector-base breakdown voltage and a doping sufficiently high to restrict base widening when the base emitter junction is forward biased.

More specifically, the inventive heterojunction bipolar transistor comprises: a sub-collector region having a collector region formed thereon, said collector region including an n-type dopant region formed therein which has a vertical width that is less than about 2000 Å and a peak concentration that is greater than a peak concentration of said collector region;

a SiGe-containing base layer formed over said collector region, said SiGe-containing base layer comprising polycrystalline regions abutting a single-crystal region; and

an emitter region formed over a portion of said single-crystal region, said emitter region including a patterned insulator having an opening which exposes a portion of said single-crystal region and an emitter polysilicon formed on said patterned insulator including within said opening.

It is noted that the inventive heterojunction bipolar transistor of the present invention may be used in a wide variety of applications, including but not limited to: a component for a mobile phone, a component for a personal digital assistant (PDA) device, a component in a portable computer, a component for a pager, a component for a hard-drive and other like applications (including wired and wireless) in which high-frequency responses, high-speeds and ruggedness are required.

### BRIEF DESCRIPTION OF THE DRAWINGS

FIG. 1 is a pictorial representation (through a cross-sectional view) of the inventive semiconductor heterojunction bipolar transistor.

FIGS. 2A-2D are pictorial representations (through cross-sectional views) illustrating the various processing steps of the present invention employed in forming the inventive semiconductor heterojunction bipolar transistor shown in FIG. 1.

### DETAILED DESCRIPTION OF THE INVENTION

The present invention, which relates to a method for improving the AC performance of a heterojunction bipolar transistor and the heterojunction bipolar transistor fabricated therefrom, will now be described in more detail by referring to the drawings that accompany the present invention. It is noted that in the accompanying drawings, like and/or corresponding elements are referred to by like reference numerals. Note also that the drawings of the present invention illustrate one bipolar device region of the structure. Other device regions including digital logic circuitry and memory regions may be formed adjacent to and abutting the bipolar device region depicted in the drawings.

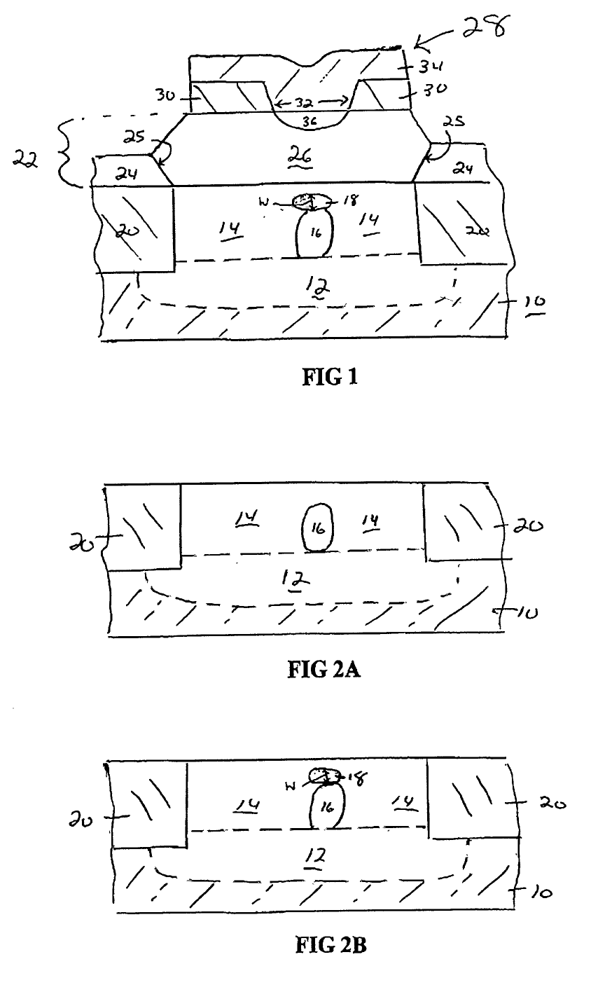

Reference is first made to FIG. 1 which is a pictorial representation (through a cross-sectional view) of the inventive heterojunction bipolar transistor. Specifically, the inventive structure shown in FIG. 1 comprises semiconductor substrate 10 of a first conductivity type (P or N) having sub-collector region 12 and collector region 14 formed therein. As shown, the collector region includes deep collector 16 which is in contact with a portion of sub-collector region 12 and a diffusion, such as n-type dopant region 18, that is formed within the collector region above deep collector 16.

In accordance with the present invention, the n-type dopant region has a vertical width, W, that is less than about 2000 Å and a peak concentration that is greater than a peak concentration of said collector region. Thus, n-type dopant region 18 is a narrow, medium doped spike in the doped collector region of a high-voltage heterojunction bipolar transistor. The inventive n-type dopant region is heavy enough however to significantly delay the onset of the Kirk effect, yet narrow enough to avoid creating a high-electric field region of sufficient duration to degrade the breakdown characteristics of the device.

In accordance with the present invention, n-type dopant region 18 has a dopant concentration of from about 5E16 to about 5E17 cm⁻³, with a dopant concentration of from about 8E16 to about 2E17 cm⁻³ being more highly preferred.

The substrate also includes isolation regions 20 which separate the bipolar device region shown in the drawings from other device regions that may be formed adjacent thereto. In addition to these elements, the substrate may further include a reach-through implant region (not shown in the drawings) which connects a portion of the sub-collector region to the surface of the substrate, and channel stop regions (not shown in the drawings) that are formed beneath deep trenches (also not shown in the drawings) of certain isolation regions.

The structure shown in FIG. 1 also includes SiGe-containing base region 22 which is formed on a surface of the substrate including on top of the isolation regions. The SiGe-containing layer includes polycrystalline regions 24 that are formed predominately over isolation regions 20 and single-crystal region 26 that is formed predominately over collector region 14. Solid lines 25 shown within SiGe-containing base layer 22 represent the facet region of the layer wherein the change over from polycrystalline to single-crystal occurs. Although not specifically labeled in the drawings, the single-crystal region of SiGe-containing base 22 includes the extrinsic and intrinsic base regions of the device.

On top of SiGe-containing base region 22 is emitter region 28 which includes patterned insulator 30, emitter opening 32 and emitter polysilicon layer 34. Note that during the course of fabricating the structure shown in FIG. 1, dopant from the emitter polysilicon diffuses into the single-crystal region of SiGe-containing base 22 so as to form emitter diffusion region 36 therein. In accordance with the present invention, emitter polysilicon is doped with a dopant opposite to the substrate; therefore the present invention contemplates PNP or NPN-type transistors.

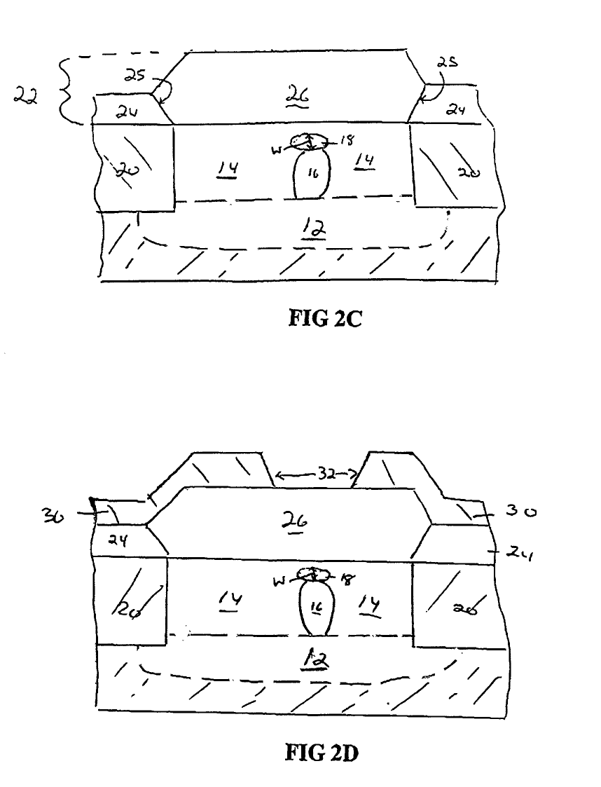

The structure shown in FIG. 1 will now be described in more detail by referring to FIGS. 2A-2D which illustrate the various processing steps that are employed in the present invention in fabricating the inventive heterojunction bipolar transistor.

Reference is first made to FIG. 2A which illustrates an initial structure that can be employed in the present invention. Specifically, the initial structure shown in FIG. 2A comprises substrate 10 having sub-collector region 12, collector region 14 and isolation regions 20 formed therein. Note that the present invention also contemplates an initial structure in which sub-collector layer 12 is formed on top of substrate 10. In such a structure, the collector and isolation regions would be formed in the sub-collector layer.

The structure shown in FIG. 2A is fabricated using conventional processes that are well known in the art and conventional materials that are also well known in the art are used in fabricating the same. For example, substrate 10 is composed of any semiconducting material including, but not limited to: Si, Ge, SiGe, GaAs, InAs, InP and other III/V compound semiconductors. Layered substrates such as Si/Si, Si/SiGe, and silicon-insulators (SOIs) are also contemplated herein. Of these semiconducting materials, it is preferred that substrate 10 be composed of Si. As mentioned above, the substrate may be an N-type substrate or a P-type substrate depending on the type of device to be subsequently formed.

Sub-collector region 12 is then formed in (or on) substrate 10 by using any well-known technique that is capable of forming a sub-collector region in such a structure. Thus, the sub-collector region may be formed via implantation or by an epitaxial growth process. Note that in the drawings the sub-collector region is formed within substrate 10 by means of ion implantation. Isolations regions 20 are then formed by either a local oxidation of silicon (LOCOS) process or by utilizing lithography, etching and trench filling.

Following the formation of isolation regions 20, collector region 14 including deep collector 16 is formed in the bipolar device region (between the two isolation regions shown) utilizing a conventional ion implantation and activation annealing processes that are well known to those skilled in the art. The ion implantation used in forming the deep collector is typically carried out at an ion dose of from about 6E12 to about 2E13 cm⁻² and at an energy of from about 350 to about 650 keV. Activation annealing, on the other hand, is typically carried out at a temperature of about 900° C. or above for a time period of about 15 seconds or less. This annealing step may be delayed until after dopant region 18 is formed within the collector region. Note that an ion implantation mask (not shown) is typically used in fabricating the deep collector of collector region 14.

Prior to removing the mask from the structure, n-type dopant region 18 is formed within collector region 14 so as to be in contact with deep collector 16. The resultant structure including n-type dopant region 18 is shown, for example, in FIG. 2B. In accordance with the present invention, n-type dopant region 18 has a width (measured vertically) that is less than about 2000 Å, and a peak concentration that is greater than a peak concentration of said collector region. More preferably, n-type dopant region 18 has a vertical width of from about 800 to about 1200 Å. Another characteristic of the inventive dopant region is that it has a doping level, i.e., concentration, that is lower than that of the base region.

The n-type dopant region is formed in the present invention using a conventional ion implantation process wherein an n-type dopant such as As, Sb, or P is employed. In one preferred embodiment of the present invention, n-type dopant region 18 is comprised of Sb; Sb is preferred since it results in the narrowest as-implanted profile as well as it diffuses much less readily than As or P. Dopant region 18 is formed using an ion implant dose of from about 2E11 to about 1E13 cm⁻² and an energy of from about 20 to about 150 keV. More preferably, n-type dopant region 18 is formed using an Sb ion dose of from about 5E11 to about 5E12 cm⁻² and an energy of from about 30 to about 50 keV.

It should be noted that the implant energies mentioned herein may vary depending on the thickness of various film layers that the implant must go through. For film layers that are thin, the above-mentioned energies are applicable. On the other hand when thick film layers are employed, higher energies than that reported herein may have to be employed. In general, the lowest possible energy should be employed so as to ensure formation of the narrowest dopant region.

Following this implant step, an annealing step may be performed using the same or different annealing conditions as mentioned hereinabove. This annealing step may activate only the n-type dopant region, or it can serve to activate both the deep collector and n-type dopant region if a previous activation-annealing step was not performed.

At this point of the inventive process, the bipolar device region shown in the drawings may be protected by forming a protective layer such as Si₃N₄ thereon, and conventional processing steps which are capable of forming adjacent device regions can be performed. After completion of the adjacent device regions and subsequent protection thereof, the inventive process continues. It should be noted that in some embodiments of the present invention, the adjacent device regions may be formed after completion of the bipolar device.

FIG. 2C illustrates the structure that is formed after SiGe-containing layer 22 is formed over the substrate including isolation regions 20 and collector region 14. The SiGe-containing layer is comprised of SiGe or SiGeC. In a highly preferred embodiment of the present invention, SiGe-containing layer 22 is comprised of SiGe. The SiGe-containing layer is formed utilizing a low temperature (on the order of about 550° C. or below) deposition process. Suitable low temperature deposition processes that can be employed in the present invention include, but are not limited to: chemical vapor deposition (CVD), plasma-assisted CVD, atomic layer deposition (ALD), chemical solution deposition, ultra-high vacuum CVD and other like deposition processes.

It is noted that the deposition process used in forming SiGe-containing layer 22 is capable of simultaneously depositing a single-crystal SiGe-containing region and abutting polycrystalline SiGe-containing regions. In accordance with the present invention, the polycrystalline regions are formed predominately over the isolation regions whereas the single-crystal region is formed predominately over the collector region. The boundary between polycrystalline and single-crystal regions is shown in FIG. 2C as a solid line and is labeled as 25. Boundary 25 is referred to herein as the facet region of the SiGe-containing base region. The orientation of the facet is a function of the underlying topography; therefore it may vary somewhat from that which is shown in the drawings.

Following formation of the SiGe-containing layer, portions of the single-crystal region, i.e., region 26, are doped via ion implantation or outdiffusion from doped polysilicon or a glass so as to form extrinsic base regions (containing the dopant) and an intrinsic base region within the single-crystal region. For clarity, the extrinsic and intrinsic base regions are not expressly labeled in the drawings of the present invention, but are meant to be included within region 26.

At this point of the inventive process, additional n-type implants may be performed into SiGe region 26 to form a shallow collector region (not shown) which provides a device that operates at high-speeds. These implants are carried out utilizing conventional processing techniques well known to those skilled in the art including, for example, ion implantation and activating annealing. At this point of the present invention, it is also possible to selectively remove portions of the SiGe-containing layer via a selective etching process so as to isolate the bipolar device shown in the drawings from other device regions. Note that the selective removal of portions of the SiGe-containing layer may occur later in the inventive method, i.e., during patterning of the emitter region.

Next, and as shown in FIG. 2D, insulator layer 30 is formed on the SiGe-containing base layer utilizing a conventional deposition process such as CVD, plasma-assisted CVD, chemical solution deposition and other like deposition processes. The insulator may be a single layer, as is shown in FIG. 2D, or alternatively, it may contain multi-insulator layers. Insulator layer 30 is composed of the same or different insulator material which is selected from the group consisting of oxides, nitrides and oxynitrides.

Emitter opening 32 is then formed in insulator 30 so as to expose a portion of single-crystal base region 26. The emitter opening is formed utilizing lithography and etching. The lithography step includes application of a photoresist (not shown), exposing the photoresist to a pattern of radiation and developing the pattern. The etching step used in the present invention is selective in removing insulator material as compared to the SiGe-containing base.

Following formation of the emitter opening, emitter polysilicon 34 is formed on the insulator layer and within the emitter opening by utilizing a conventional deposition process such as CVD. The emitter polysilicon and insulator layer are then selectively removed so as to form emitter region 28 on the SiGe-base providing the structure shown in FIG. 1. Specifically, lithography and etching are employed in patterning the insulator layer and emitter polysilicon. It is noted that a single etching step may be performed, or separate etching steps may also be employed.

Conventional BiCMOS processing steps may then performed on the structure shown in FIG. 1. Note that during one of the additional BiCMOS processes steps, dopant from emitter polysilicon is diffused via the emitter opening into the underlying single-crystal SiGe-containing base region forming emitter diffusion region 36 therein.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

Having thus described our invention in detail, what we claim is new and desire to secure by the Letters Patent is:

1. A method of fabricating a semiconductor device comprising the steps of:
(a) providing a collector having a first doping type, said collector comprising a sub-collector and a diffusion;
(b) providing the diffusion over said sub-collector, said diffusion having said first doping type;
(c) forming a base;
(d) forming an emitter; and
wherein said diffusion has a vertical width sufficiently narrow to avoid lowering collector-base breakdown voltage and a doping sufficiently high to restrict base widening when the base-emitter junction is forward biased.

2. The method of claim 1 wherein in said providing step (b) said vertical width of said diffusion is less than about 2000 Å.

3. The method of claim 2 wherein in said providing step (b) said vertical width of said diffusion is from about 800 to about 1200 Å.

4. The method of claim 1 wherein in said providing step (b) said diffusion has a peak doping concentration and said collector has a peak doping concentration, wherein said peak doping concentration of said diffusion is greater than said peak doping concentration of said collector.

5. The method of claim 1 wherein in said providing step (c) said base has a peak doping concentration and wherein said diffusion has a peak doping concentration that is lower than said peak doping concentration of said base.

6. The method of claim 1 wherein in said providing step (b) said diffusion comprises a dopant selected from the group consisting of As, Sb and P.

7. The method of claim 6 wherein said dopant is Sb.

8. The method of claim 6 wherein in said providing step (b) said diffusion is formed by ion implantation and activation annealing.

9. The method of claim 8 wherein said ion implantation is performed at an ion dose of from about 2E11 to about 1E13 cm⁻² and at an energy of from about 20 to about 150 keV.

10. The method of claim 9 wherein said ion implantation is performed at an ion dose of from about 5E11 to about 5E12 cm⁻² and at an energy of from about 30 to about 50 keV.

11. The method of claim 8 wherein said activation annealing is performed at a temperature of about 900° C. or higher for about 15 seconds or less.

12. The method of claim 1 wherein in said forming step (c) said diffusion is located adjacent the base-collector junction.

13. The method of claim 1 wherein in said forming step (c) further comprises providing a lightly doped collector separating said diffusion from said base.

14. The method of claim 13 wherein in said forming step (c) said lightly doped collector has a vertical width of about 1000 to about 3000 Å.

15. The method of claim 1 wherein said forming step (c) comprises forming a heterojunction.

16. The method of claim 15 wherein in said step of forming a heterojunction comprises depositing a SiGe-containing layer on said collector, said SiGe-containing layer comprising a polycrystalline region abutting a single-crystal region.

17. The method of claim 16 wherein said forming step (d) includes forming a patterned insulator on said SiGe-containing layer, wherein said patterned insulator includes an opening that exposes a portion of said single-crystal region, and forming an emitter polysilicon on said patterned insulator and in said opening.

18. The method of claim 17 wherein said step of forming a patterned insulator on said SiGe-containing layer comprises lithography and etching.

19. The method of claim 16 wherein portions of said single-crystal region are doped so as to form extrinsic base regions therein.

20. The method of claim 16 wherein said SiGe-containing layer comprises SiGeC.

21. The method of claim 16 wherein said step of depositing a SiGe-containing layer is performed using a low-temperature deposition process selected from the group consisting of chemical vapor deposition (CVD), plasma-assisted CVD, atomic layer deposition (ALD), chemical solution deposition and ultra-high vacuum CVD.

22. The method of claim 21 wherein said collector includes a deep collector that is formed by ion implantation and annealing.

23. The method of claim 1 wherein in said providing step (a) said sub-collector is formed by ion implantation into a substrate or by epitaxially growing said sub-collector on a substrate.

24. A bipolar transistor comprising:
an emitter, a base, a collector, a base-emitter junction, and a base-collector junction, wherein said collector comprises a sub-collector and a diffusion between said sub-collector and said base-collector junction, wherein said diffusion has a vertical width sufficiently narrow to avoid lowering collector-base breakdown voltage and a doping sufficiently high to restrict base widening when the base-emitter junction is forward biased.

25. The bipolar transistor of claim 24 wherein said diffusion is located adjacent the base-collector junction.

26. The bipolar transistor of claim 24 wherein said vertical width of said diffusion is less than about 2000 Å.

27. The bipolar transistor of claim 26 wherein said vertical width of said diffusion is from about 800 to about 1200 Å.

28. The bipolar transistor of claim 24 wherein said diffusion has a peak doping concentration and said collector has a peak doping concentration, wherein said peak doping concentration of said diffusion is greater than said peak doping concentration of said collector.

29. The bipolar transistor of claim 24 wherein said base has a peak doping concentration and wherein said diffusion has a peak doping concentration that is lower than said peak doping concentration of said base.

30. The bipolar transistor of claim 24 wherein said diffusion comprises a dopant selected from the group consisting of As, Sb and P.

31. The bipolar transistor of claim 30 wherein said dopant is Sb.

32. The bipolar transistor of claim 24 further comprising a lightly doped collector separating said diffusion from said base.

33. The bipolar transistor of claim 32 wherein said lightly doped collector has a vertical width of about 1000 to about 3000 Å.

34. The bipolar transistor of claim 24 wherein said diffusion provides a higher speed of the transistor by restricting base widening.

35. The bipolar transistor of claim 24 wherein said sub-collector is on a semiconductor substrate.

36. The bipolar transistor of claim 35 wherein said semiconductor substrate is a semiconducting material selected from the group consisting of Si, Ge, SiGe, GaAs, InAs, InP, Si/Si, Si/SiGe and silicon-on-insulators.

37. The bipolar transistor of claim 24 wherein said diffusion has a dopant concentration of from about 5E16 to about 5E17 cm⁻³.

38. The bipolar transistor of claim 24 wherein said diffusion has a dopant concentration of from about 8E16 to about 2E17 cm⁻³.

39. The bipolar transistor of claim 24 wherein the transistor comprises a heterojunction.

40. The bipolar transistor of claim 39 wherein said heterojunction comprises a SiGe-containing base layer on a silicon substrate.

41. The bipolar transistor of claim 40 wherein said SiGe-containing base layer comprises a polycrystalline region abutting a single-crystal region.

42. The bipolar transistor of claim 41, wherein said emitter comprises polycrystalline silicon contacting a portion of said single-crystal region through an opening in a patterned insulator.

43. The bipolar transistor of claim 41 wherein said single-crystal region includes extrinsic and intrinsic base regions.

44. The bipolar transistor of claim 40 wherein said SiGe-containing base layer comprises SiGeC.
